(19) United States
(12) Patent Application Publication
(10) Pub. No.: US 2016/0191077 A1
(43) Pub. Date: Jun. 30, 2016

(54) MAGIC STATE GENERATION APPARATUS, MAGIC STATE GENERATION METHOD, AND QUANTUM GATE OPERATION METHOD

(71) Applicant: Kabushiki Kaisha Toshiba, Minato-ku (JP)

(72) Inventors: Hayato GOTO, Kawasaki (JP); Kouichi Ichimura, Yokohama (JP); Satoshi Nakamura, Tokyo (JP); Mamiko Kujiraoka, Kawasaki (JP)

(73) Assignee: Kabushiki Kaisha Toshiba, Minato-ku (JP)

(21) Appl. No.: 15/060,031

(22) Filed: Mar. 3, 2016

Related U.S. Application Data
(63) Continuation of application No. PCT/JP2015/054901, filed on Feb. 16, 2015.

(30) Foreign Application Priority Data
Feb. 18, 2014 (JP) 2014-028793

(51) Int. Cl. H03M 13/09; G06N 99/00; H03M 13/29

(52) U.S. Cl. CPC H03M 13/09; H03M 13/2906; G06N 99/002

(57) ABSTRACT

According to one embodiment, a magic state generation apparatus includes first encoder, state distiller, second encoder, and error detector. The first encoder encodes a magic state of a physical quantum bit into a level-1 encoded magic state. The state distiller receives n level-L encoded magic states, performs error detection when reading a level-L encoded quantum bit, performs post-selection which accepts the encoded quantum bit only when no error is detected, and outputs k level-L encoded magic states each having a low error probability (1≦L≦M−1, and k<n). The second encoder encodes a level-L into a level-(L+1) encoded magic states. The error detector performs error detection on the level-(L+1) encoded magic state, and obtains a level-(L+1) encoded magic state from which an error is removed.

### CROSS-REFERENCE TO RELATED APPLICATIONS

This application is a Continuation application of PCT Application No. PCT/JP2015/054901, filed Feb. 16, 2015 and based upon and claiming the benefit of priority from Japanese Patent Application No. 2014-028793, filed Feb. 18, 2014, the entire contents of which are incorporated herein by reference.

### FIELD

Embodiments described herein relate generally to a magic state generation apparatus, magic state generation method, and quantum gate operation method for a fault-tolerant quantum computation.

### BACKGROUND

Since a quantum computer uses a quantum-mechanical superposition state, decoherence which destroys this state causes a memory error or gate error. This does not occur in conventional classical computers, it is a problem unique to quantum computers. Therefore, a fault-tolerant quantum computation using a quantum error correction code capable of correcting these kinds of errors is regarded as indispensable in quantum computers.

Normally, quantum error correction coding makes it possible to easily execute basic gates (e.g., a Pauli gate, Hadamard gate, and/or controlled NOT gate) at a low error probability. However, universal quantum computations cannot be executed by using these gates alone. Therefore, magic state distillation is necessary (S. Bravyi and A. Kitaev, Phys. Rev. A71, 022316 (2005), and N. C. Jones at al., Phys. Rev. X2, 031007 (2012)). The magic state is a special state such that universal quantum computations can be executed by combining this state and basic gates, and the error probability can be decreased by using only basic gates. Also, magic state distillation is a process of generating a few magic states having a low error probability by using a plurality of magic states having a high error probability.

Presently, however, the number of resources necessary for magic state distillation is very large, and this is a serious problem of the fault-tolerant quantum computation.

### BRIEF DESCRIPTION OF THE DRAWINGS

FIG. 1 is a method and apparatus for generating a magic state of a logical quantum bit having an error probability equivalent to a physical error probability.

FIG. 2 is a view showing conventional magic state distillation.

FIG. 3 is a view showing a magic state generation apparatus and magic state generation method of an embodiment.

FIG. 4 is a view showing an example of a C₄-code quantum encoder.

FIG. 5 is a view showing an example of a C₆-code quantum encoder.

FIG. 6 is a view showing an example of a quantum encoder for a quantum error detection code H₆.

FIG. 7 is a view showing an example of a magic state distillation using the quantum error detection code H₆.

FIG. 8 is a view showing an example for implementing a controlled Hadamard gate shown in FIG. 7.

FIG. 9 is a view showing an example for implementing R_{Y}(π/8) shown in FIG. 8.

FIG. 10 is a view showing an example for generating a magic entangled state of the second embodiment.

FIG. 11 is a view showing magic teleportation of the second embodiment.

### DETAILED DESCRIPTION

The present embodiment has been made in consideration of the above situation, and its object is to provide a magic state generation apparatus, magic state generation method, and quantum gate operation method of generating a magic state using fewer resources.

According to an embodiment, a magic state generation apparatus is a magic state generation apparatus for generating a level-M (M is a natural number) encoded magic state encoded by level-M concatenated quantum codes, and includes a first quantum encoder, magic state distiller, second quantum encoder, and error detector. The first quantum encoder encodes a magic state of a physical quantum bit into a level-1 encoded magic state. The magic state distiller receives n level-L encoded magic states, performs error detection when reading a level-L encoded quantum bit, performs post-selection which accepts the encoded quantum bit only when no error is detected, and outputs k level-L encoded magic states each having a low error probability (L, n, and k are natural numbers, 1≦L≦M−1, and k<n). The second quantum encoder encodes a level-L encoded magic state into a level-(L+1) encoded magic state. The error detector performs error detection on the level-(L+1) encoded magic state, and obtains a level-(L+1) encoded magic state from which an error is removed.

A magic state generation apparatus, magic state generation method, and quantum gate operation method according to an embodiment will be explained in detail below with reference to the accompanying drawings. Note that in the following embodiment, parts denoted by the same reference numeral perform the same operation, and a repetitive explanation will be omitted.

In the embodiment, a magic state can be generated with fewer resources, and as a result the resources necessary for a fault-tolerant quantum computation can be reduced.

In this embodiment, quantum error correction codes are limited to concatenated quantum codes. In particular, an efficient soft-decision decoder can be used for concatenated small-sized CSS codes (H. Goto et al., Sci. Rep. 3, 2044 (2013)).

Concatenated quantum codes have a plurality of levels (E. Knill, Nature 434, 39 (2005)). Level-0 corresponds to a physical quantum bit. A level-1 encoded quantum bit is encoded by using the physical quantum bit. Similarly, a level-(L+1) encoded quantum bit is encoded by using a level-L encoded quantum bit (L is a natural number, and L=1, 2, 3, . . . ). An encoded quantum bit having a sufficiently high level is used in quantum computations. A highest-level encoded quantum bit to be used in quantum computations is specifically called a logical quantum bit.

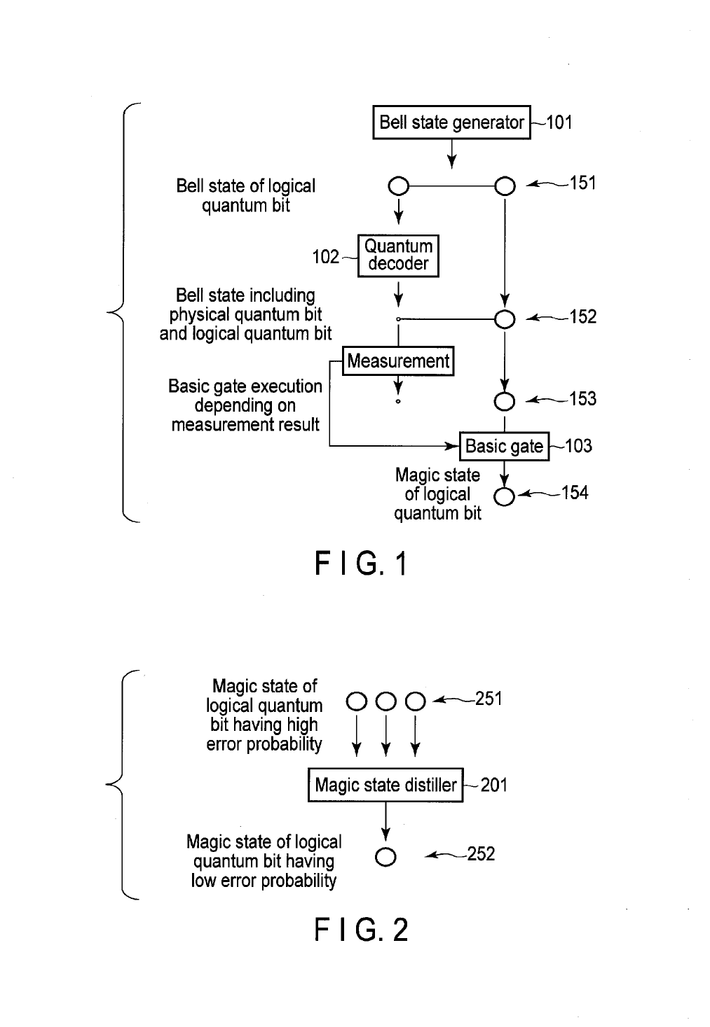

Next, a conventional magic state generation method for concatenated quantum codes (E. Knill, Nature 434, 39 (2005)) will be explained with reference to FIGS. 1 and 2.

First, a magic state of a logical quantum bit having a high error probability is generated (FIG. 1). For this purpose, a Bell state generator 101 generates a Bell state 151 including logical quantum bits, a quantum decoder 102 returns one logical quantum bit included in the Bell state 151 to a physical quantum bit, and the physical quantum bit is measured by an appropriate base. The quantum decoder 102 is a device for converting a logical quantum bit into a physical quantum bit. By this measurement, the other logical quantum bit of the Bell state 151 is projected onto a magic state or a state orthogonal to the magic state (in accordance with the measurement result). When an orthogonal state 153 is obtained, a basic gate 103 converts the orthogonal state 153 into a magic state 154. Thus, the magic state 154 of the logical quantum bit having an error probability equivalent to a physical error probability is obtained.

Then, a plurality of magic states 154 of logical quantum bits with a high error probability are generated (251), and a magic state 252 having a low error probability is obtained by using a magic state distiller 201 (see FIG. 2). The magic state distiller 201 can be formed by using only basic gates, and the error probabilities of the basic gates are sufficiently low and negligible because the gates are encoded ones. (For the sake of simplicity, the magic state distiller 201 includes three inputs and one output in FIG. 2. However, in general, any number of inputs and outputs may be used.)

A typical magic state distillation method is to distill one magic state from fifteen magic states, and the error probability decreases from p to 35p³ (S. Bravyi and A. Kitaev, Phys. Rev. A71, 022316 (2005); and N. C. Jones et al., Phys. Rev. X2, 031007 (2012)). If the error probability does not sufficiently decrease even by this method, fifteen distilled magic states are prepared and distilled again. Consequently, the error probability becomes 35(35p³)³=1.5×10⁶×p⁹. The number of magic states necessary for this method is 15²=225 when they are obtained by the method shown in FIG. 1. Thus, the conventional problem is that it is necessary to initially prepare a large number of logical-quantum-bit magic states. In practice, even the basic gates have low error probabilities, so the error probability of a reachable magic state is finally restricted by the error probabilities of the basic gates. Therefore, the error probability of the magic state cannot be lower than those of the basic gates.

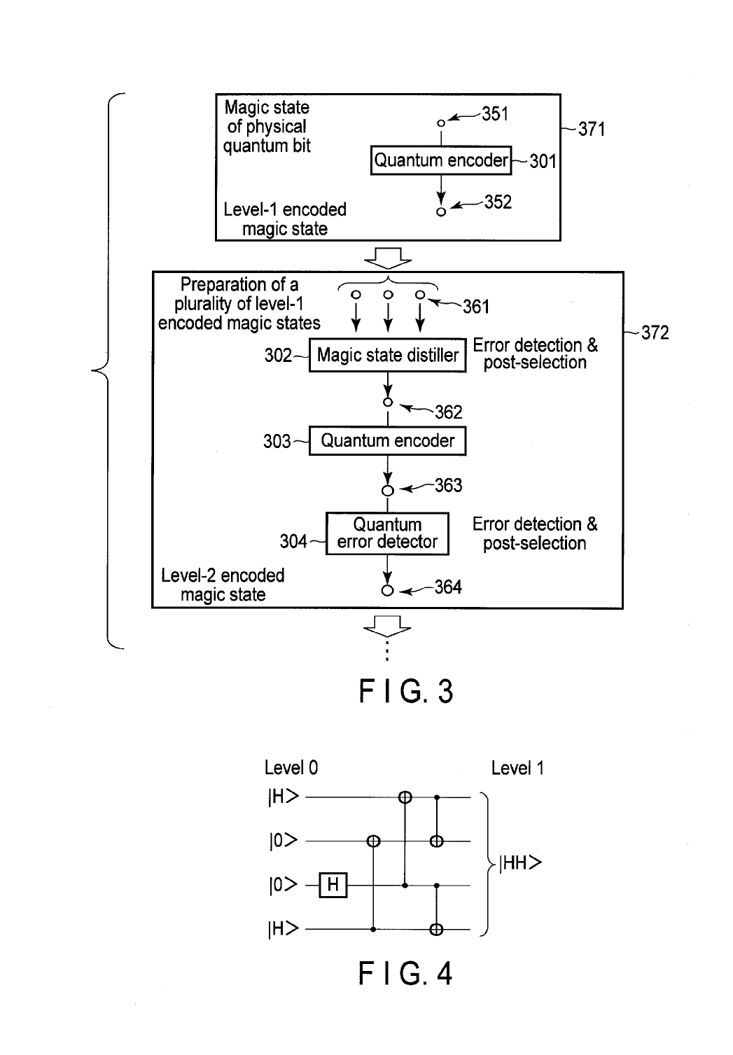

Next, the magic state generation apparatus and magic state generation method of the embodiment will be explained with reference to FIG. 3. The method of the embodiment is a bottom-up method which sequentially generates magic states in ascending order of level. Low-level magic state distillation seems to be unsuccessful because the error probabilities of the basic gates are not negligible. However, the error probabilities can be decreased by successfully using error detection and post-selection. This is an important feature of the magic state generation apparatus, magic state generation method, and quantum gate operation method of this embodiment.

First, a physical quantum bit 351 in the magic state is prepared. Then, a quantum encoder 301 converts this physical quantum bit into a level-1 encoded quantum bit. In this manner, a level-1 encoded magic state having an error probability equivalent to a physical error probability is obtained.

Subsequently, a plurality of level-1 encoded magic states are prepared, and a magic state distiller 302 generates a level-1 encoded magic state 362 having a low error probability from a plurality of encoded magic states 361. In this method, the error probabilities of the basic gates used in the magic state distiller 302 must be sufficiently low, and this can be achieved by error detection and post-selection using a level-1 code. That is, low error probabilities are maintained by performing error detection, and performing post-selection by which error detection is performed again if an error is detected, and the process is continued if no error is detected. It is also possible to reduce resources to be used by setting minimum necessary error detection portions.

Next, a quantum encoder 303 converts the level-1 encoded magic state 362 having a low error probability into a level-2 encoded magic state 363. A quantum error detector 304 using a level-2 code removes an error having occurred in the quantum encoder 303. The quantum error detector 304 can be implemented by only basic gates, e.g., by error-detecting teleportation (H. Goto et al., Sci. Rep. 3, 2044 (2013)).

Note that the quantum encoder 301 performs encoding to a level-(L+1) encoded quantum bit by using a level-L encoded quantum bit. In other words, the quantum encoder 301 encodes the level-L encoded quantum bit into the level-(L+1) encoded quantum bit.

A level-3 encoded magic state can be obtained by performing a similar process 372 by using a level-2 encoded magic state 364 thus obtained. By continuing this to the level of a logical quantum bit, it is possible to obtain a magic state of a logical quantum bit having a sufficiently low error probability.

Unlike the conventional method, the method of this embodiment mainly uses a state having a level lower than that of a logical quantum bit, and thus has an effect of reducing necessary resources (the number of physical quantum bits and the number of physical gates).

Finally, a gate operation (not included in the basic gates) using the magic state is executed, but without directly using the magic state, by quantum teleportation using a special entangled state obtained by using the magic state. This can further reduce the resources and error probability as will be explained below.

To perform the gate operation not included in the basic gates by using the magic state, a plurality of basic gates are necessary (see, e.g., FIG. 9). When the magic state is prepared by the method of this embodiment, the error probability and resources of the magic state are equivalent to those of the basic gate, so the error probability and resources of the basic gate are no longer negligible.

This gate operation may also be executed by quantum teleportation using an entangled state obtained by using the magic state. This entangled state will be called a “magic entangled state” hereinafter, and this teleportation will be called “magic teleportation” hereinafter. A magic entangled state having a low error probability can be generated by performing error detection at the end of the generation of the magic entangled state. By performing the gate operation by magic teleportation using this magic entangled state, it is possible to further reduce the error probability and resources.

### EXAMPLES

As a practical example, a case using C₄/C₆ codes of Knill (E. Knill, Nature 434, 39 (2005)); H. Goto et al., Sci. Rep. 3, 2044 (2013)) will be explained in detail. The C₄/C₆ codes are concatenated quantum codes by which level-1 is encoded by a C₄ code, and level-2 or higher is encoded by a C₆ code. Both C₄ and C₆ are codes for encoding two quantum bits. As the logical quantum bit, one of two encoded quantum bits having the highest level is used. In this example, level-3 is used as the logical quantum bit as an example.

In the first example, the magic state generation apparatus and magic state generation method shown in FIG. 3 will be explained. In the second example, the quantum gate operation method performed by magic teleportation will be explained. (Unlike the above-mentioned references, the definitions of an encoded Pauli operator with respect to the two encoded quantum bits of the C₆ code are XIXIXIX, ZIZIZIZ, IXIXIX, and IZIZIZ. This enables the transversal execution of an Hadamard gate.)

As the magic state, |H> below as the eigenstate of eigenvalue 1 of an Hadamard operator H is used.

$$\vert H 〉 = cos \frac{π}{8} \vert 0 〉 + sin \frac{π}{8} \vert 1 〉$$

To perform universal quantum computations by using the C₄/C₆ codes, |Y> below as the eigenstate of eigenvalue 1 of a Y operator is also necessary.

$$\vert Y 〉 = \frac{\vert 0 〉 + i \vert 1 〉}{\sqrt{2}}$$

A method of generating |Y>, however, can be performed by only changing a controlled Hadamard gate for use in the generation of |H> into a controlled Y gate, and, unlike the controlled Hadamard gate, the controlled Y gate can easily be executed by only the basic gate, so the |Y> generation method is easier. Therefore, only |H> will be explained below.

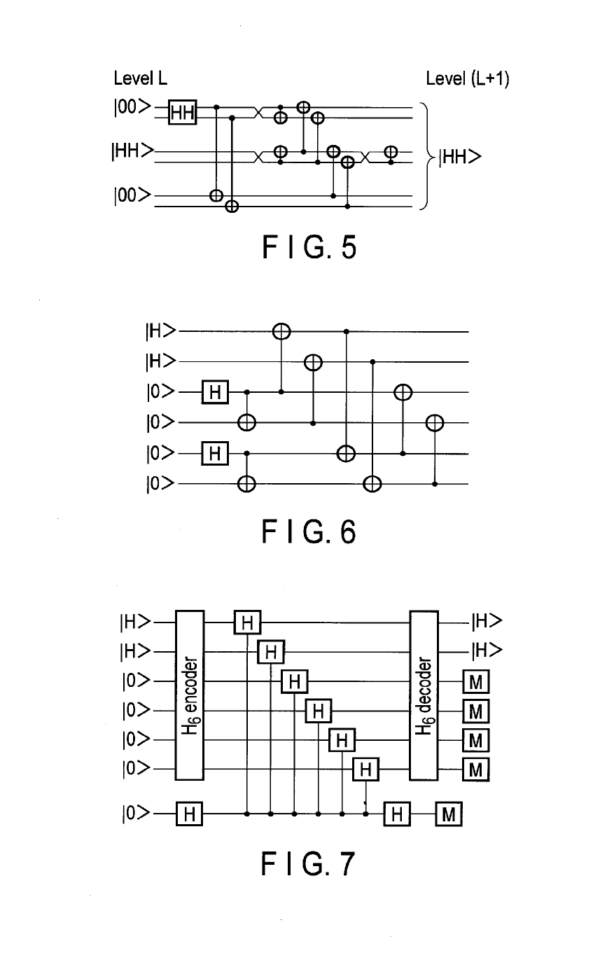

FIGS. 4 and 5 respectively show a C₄-code quantum encoder and C₆-code quantum encoder. (Both C₄ and C₆ are encoding of two quantum bits in FIG. 5, so state vectors are drawn as a pair in FIGS. 4 and 5, but this does not apply to the following explanation for the sake of simplicity.) Quantum decoders perform the reverse operation of this.

Note that in the following simulation, only an error of a physical controlled NOT gate is taken into consideration as an error, and the error probability is 0.4% (a physical controlled NOT gate need only be taken into account as an error, and this is described in H. Goto et al., Sci. Rep. 3, 2044 (2013)).

### First Example

FIG. 7 shows a method of distilling |H> by using a quantum error detection code H₆ having an encoder shown in FIG. 6. H₆ is a code for encoding two quantum bits by using six quantum bits; stabilizer generators are defined by XXXXII, IIXXXX, ZZZZII, and IIZZZZ, and encoded Pauli gates are defined by XIXIXI, ZIZIZI, IXIXIX, and IZIZIZ. H₆ can transversally execute the Hadamard gate, and can be used in magic state distillation (C. Jones, Phys. Rev. A 87, 042305 (2013)). M is the readout of an encoded quantum bit, and decoding used in this readout performs error detection (H. Goto et al., Sci. Rep. 3, 2044 (2013)), and, if an error is detected, outputs a symbol e indicating the error. Only when all M outputs are Os does post-selection accept this encoded quantum bit, thereby obtaining |H> having a low error probability.

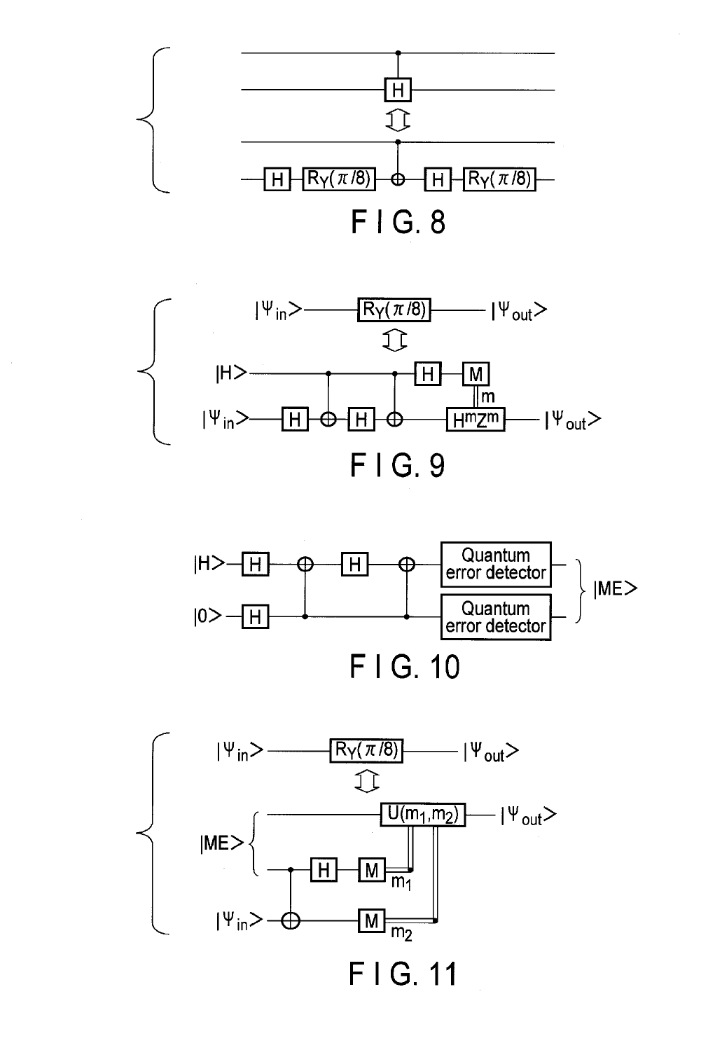

The controlled Hadamard gate shown in FIG. 7 can be implemented as shown in FIG. 8. R_{Y}(π/8) in FIG. 8 is defined by:

$$\begin{matrix}{R}_{Y} ( π / 8 ) \vert 0 〉 = cos \frac{π}{8} \vert 0 〉 + sin \frac{π}{8} \vert 1 〉 , \\ {R}_{Y} ( π / 8 ) \vert 1 〉 = - sin \frac{π}{8} \vert 0 〉 + cos \frac{π}{8} \vert 1 〉\end{matrix}$$

R_{Y}(π/8) can be implemented as shown in FIG. 9. Referring to FIG. 9, M is the readout of an encoded quantum bit as mentioned above, and decoding used in this readout performs error detection, and, if an error is detected, outputs the symbol e indicating the error. Then, post-selection which accepts the encoded quantum bit is performed only when no error is detected, thereby decreasing the error probability. Also, m is the result of the read M, and is 0 or 1. From the foregoing, the controlled Hadamard gate requires two |H>'s in addition to the input |H>'s shown in FIG. 7, therefore, seven |H>'s are required to distill one |H>.

In level-1 magic state distillation for obtaining a level-2 magic state, all encoded controlled NOT gates are executed by transversally performing physical controlled NOT gates. In level-2 magic state distillation for obtaining a level-3 magic state, all encoded controlled NOT gates are executed by transversally performing physical controlled NOT gates. However, immediately after two initial encoded controlled NOT gates of the H₆ encoder shown in FIG. 6, and immediately after an initial encoded controlled NOT gate for R_{Y}(π/8) shown in FIG. 9, error detection and post-selection are performed by error-detecting teleportation (H. Goto et al., Sci. Rep. 3, 2044 (2013)).

The quantum encoder shown in FIG. 3 is implemented by FIG. 6, and the quantum error detector shown in FIG. 3 is implemented by error-detecting teleportation (H. Goto et al., Sci. Rep. 3, 2044 (2013)). Thus, the magic state generation apparatus and magic state generation method of this embodiment shown in FIG. 3 are implemented.

A numerical simulation of magic state generation was performed in accordance with the above-described method.

In the following description, resources are represented by a value obtained by dividing the total number of necessary physical quantum bits by the total number (2.5×10³ on average) of physical quantum bits necessary to prepare one magic state having a high error probability by the conventional method shown in FIG. 1 (the resources include the effect of post-selection). (The error probability of a magic state generated by the method shown in FIG. 1 is about 0.42%). When the magic state generation apparatus and magic state generation method of this embodiment were used, the resources were about 4.8, and the error probability was about 0.9×10⁻⁶. On the other hand, when fifteen magic states each having a high error probability were prepared by the conventional method shown in FIG. 1 and the above-described standard magic state distillation was performed on them, the resources were about 115, and the error probability was about 21×10⁻⁶. In this simulation, the error probability (about 4×10⁻⁶) and resources (about 2.7) of the logic controlled NOT gate were also taken into consideration.

From the foregoing, the effect of the magic state generation apparatus and magic state generation method of this embodiment is obviously superior to that of the conventional method. Note that the error and resources of the logic controlled NOT gate have a large influence on the height of the error probability and the large number of necessary resources of the conventional method.

The conventional theory assumes a procedure in which many magic states each having a high error probability are prepared first, and distillation is then performed using the basic gate of a logic level having a negligible error probability. Accordingly, the error probability and resources of a generated magic state cannot be less than those of the basic gate (particularly, the logic controlled NOT gate). By contrast, the magic state generation apparatus and magic state generation method of this embodiment implement magic state distillation at a level lower than the logic level by successfully using error detection and post-selection, thereby achieving an error probability and resources equivalent to those of the logic controlled NOT gate. Thus, the magic state generation apparatus and magic state generation method of this embodiment can exceed the limit of the conventional method.

### Second Example

A magic entangled state, magic teleportation, and a quantum gate operation method when executing R_{Y}(π/8) by using |H> will be explained below.

A magic entangled state |ME> is given by:

$$\vert ME 〉 = \vert 0 〉 ( cos \frac{π}{8} \vert 0 〉 + sin \frac{π}{8} \vert 1 〉 ) + \vert 1 〉 ( - sin \frac{π}{8} \vert 0 〉 + cos \frac{π}{8} \vert 1 〉 )$$

|ME> is generated as shown in FIG. 10. In this example as shown in FIG. 10, error detection and post-selection are performed at the end of the generation of |ME>.

FIG. 11 shows a quantum gate operation method of executing R_{Y}(π/8) by quantum teleportation using this |ME>. A gate operation U(m₁, m₂) depending on the measurement results shown in FIG. 11 is defined as:

$$U ( {m}_{1} , {m}_{2} ) = \{ \begin{matrix}I & ⋯ {m}_{1} = 0 , {m}_{2} = 0 \\ H & ⋯ {m}_{1} = 1 , {m}_{2} = 0 \\ XHX & ⋯ {m}_{1} = 0 , {m}_{2} = 1 \\ XZ & ⋯ {m}_{1} = 1 , {m}_{2} = 1\end{matrix}$$

This operation can be executed by basic gates alone.

A numerical simulation of generating |ME> by the method shown in FIG. 10 and executing R_{Y}(π/8) by the method shown in FIG. 11 was performed. As a result, the gate error probability was 2.3×10⁻⁶, and necessary resources were 7.2. On the other hand, when |H> was prepared by the method of the first example and R_{Y}(π/8) was executed by the method shown in FIG. 9, the gate error probability was 8.5×10⁻⁶, and the resources were 10.1. As described above, magic teleportation can reduce the error probability of the gate operation and the necessary resources.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A magic state generation apparatus for generating a level-N (N is a natural number) encoded magic state encoded by level-N concatenated quantum codes, comprising:
a first quantum encoder configured to encode a magic state of a physical quantum bit into a level-1 encoded magic state;
a magic state distiller configured to receive n level-L encoded magic states, perform error detection when reading a level-L encoded quantum bit, perform post-selection which accepts the encoded quantum bit only when no error is detected, and to output k level-L encoded magic states each having a low error probability (L, n, and k are natural numbers, 1≦L≦N−1, and k<n);
a second quantum encoder configured to encode a level-L encoded magic state into a level-(L+1) encoded magic state; and
a quantum error detector configured to perform error detection on the level-(L+1) encoded magic state, and to obtain a level-(L+1) encoded magic state from which an error is removed.

2. The apparatus according to claim 1, wherein the magic state distiller includes a plurality of level-L or level-(L−1) quantum error detectors, and each of the plurality of quantum error detectors performs the error detection.

3. A magic state generation method of generating a level-N (N is a natural number) encoded magic state encoded by level-N concatenated quantum codes, comprising:
encoding a magic state of a physical quantum bit into a level-1 encoded magic state;
receiving n level-L encoded magic states, performing error detection when reading a level-L encoded magic state, performing post-selection which accepts the encoded quantum bit only when no error is detected, and outputting k level-L encoded magic states having a low error probability (L, n, and k are natural numbers, 1≦L≦N−1, and k<n);
encoding a level-L encoded magic state into a level-(L+1) encoded magic state; and
performing error detection on the level-(L+1) encoded magic state, and obtaining a level-(L+1) encoded magic state from which an error is removed.

4. The method according to claim 3, wherein after the level-L encoded magic state is input and before the level-L encoded magic state is output, the error detection is performed when reading one of a level-L encoded quantum bit and a level-(L−1) encoded quantum bit, and post-selection which accepts the encoded quantum bit is performed only when no error is detected.

5. A quantum gate operation method of performing R_{Y}(π/8) on a level-N(N is a natural number) encoded quantum bit encoded by level-N concatenated quantum codes, comprising:
executing a magic state generation method cited in claim 3 by using an eigenstate |H> of an Hadamard operator given by:
$$\vert H 〉 = cos \frac{π}{8} \vert 0 〉 + sin \frac{π}{8} \vert 1 〉$$
as a magic state;
executing basic gates on encoded |H> and encoded |0>, performing error detection when reading a level-N encoded quantum bit, performing post-selection which accepts the encoded quantum bit only when no error is detected, and outputting a magic entangled state |ME> having a low error probability given by:
$$\vert ME 〉 = \vert 0 〉 ( cos \frac{π}{8} \vert 0 〉 + sin \frac{π}{8} \vert 1 〉 ) + \vert 1 〉 ( - sin \frac{π}{8} \vert 0 〉 + cos \frac{π}{8} \vert 1 〉 ) ;$$
and
executing R_{Y}(π/8) by teleportation using the magic entangled state.

6. A quantum gate operation method of performing R_{Y}(π/8) on a level-N (N is a natural number) encoded quantum bit encoded by level-N concatenated quantum codes, comprising:
executing a magic state generation method cited in claim 4 by using an eigenstate |H> of an Hadamard operator given by:
$$\vert H 〉 = cos \frac{π}{8} \vert 0 〉 + sin \frac{π}{8} \vert 1 〉$$
as a magic state;
executing basic gates on encoded |H> and encoded |0>, performing error detection when reading a level-N encoded quantum bit, performing post-selection which accepts the encoded quantum bit only when no error is detected, and outputting a magic entangled state |ME> having a low error probability given by:
$$\vert ME 〉 = \vert 0 〉 ( cos \frac{π}{8} \vert 0 〉 + sin \frac{π}{8} \vert 1 〉 ) + \vert 1 〉 ( - sin \frac{π}{8} \vert 0 〉 + cos \frac{π}{8} \vert 1 〉 ) ;$$
and
executing R_{Y}(π/8) by teleportation using the magic entangled state.
